(19) United States
(12) Patent Application Publication
(10) Pub. No.: US 2021/0309880 A1
(43) Pub. Date: Oct. 7, 2021

(54) DIRECT TO SUBSTRATE COATING VIA IN SITU POLYMERIZATION

(71) Applicant: Henkel AG & Co. KGaA, Duesseldorf (DE)

(72) Inventors: Thomas S. Smith, II, Novi, MI (US); John L. Zimmerman, Taylor, MI (US); John D. McGee, Troy, MI (US); Gregory T. Donaldson, Sterling Heights, MI (US); Lisa K. Miller, Clinton Township, MI (US); William G. Kozak, Waterford, MI (US); Eric C. Kuhns, Washington, MI (US)

(21) Appl. No.: 17/352,434

(22) Filed: Jun. 21, 2021

Related U.S. Application Data
(63) Continuation of application No. PCT/US2019/065137, filed on Dec. 9, 2019.
(60) Provisional application No. 62/782,004, filed on Dec. 19, 2018.

(51) Int. Cl. C09D 133/14; C08F 120/20; H05K 3/28

(52) U.S. Cl. CPC C09D 133/14; H05K 3/285; C08F 120/20

(57) ABSTRACT

Disclosed is a process that utilizes a modified Atom Transfer Radical Polymerization (ATRP) process to form a water-resistant coating in situ on a substrate. The process uses solvent soluble monomers, initiator and ligand to form a solvent insoluble water-resistant polymer coating that is deposited directly onto a metal trace on the substrate. The process is especially useful for providing a water-resistant coating to the circuits on a printed circuit board, wearable electronics, and biological sensors. The process can be run in an aqueous solvent in the open atmosphere and does not require a vacuum, heating steps or masking. The coating is deposited only on the metal trace and closely adjacent areas of the substrate.

### TECHNICAL FIELD

This disclosure relates generally to monomer-containing coating compositions and more particularly to such compositions which polymerize in situ directly on at least a portion of a substrate thereby forming a polymer coating on at least a portion of the substrate. The disclosure is also directed to methods of making such coating compositions, methods of depositing the polymer coating in situ and to substrates coated with the polymer coating.

### BACKGROUND OF THE DISCLOSURE

This section provides background information which is not necessarily prior art to the inventive concepts associated with the present disclosure.

Many substrate surfaces benefit from the application of various types of coatings onto the surfaces, such as decorative layers, functional layers, e.g. layers that allow passage of certain chemicals, fingerprint resistance, anti-corrosion protection and in some cases the coating is desirably a water-resistant coating. Water-resistant coatings find special use in application to electronic equipment. Many electronics include printed circuit boards (PCB), which are an essential building block of electronics systems ranging from calculators to cell phones.

In order to maintain performance of electronic devices under diverse service environment conditions, it is often desirable to apply a coating to specific surfaces. Examples of critical surfaces in electronic devices include printed circuit boards, wearable electronics such as adherent patches and wearable body-monitoring devices, and conductive traces associated with sensors including in-body sensors. Printed circuit boards mechanically support and electrically connect electronic components or electrical components using conductive traces adhered or otherwise attached to a non-conductive substrate. It has become increasingly important to achieve moisture resistant printed circuit boards (PCB), and to maintain functionality in a range of environments, particularly in the handheld electronics markets. Attempts to protect electronics often use some form of conformal coating over the entire printed circuit board. Conformal coating material is a polymeric film which conforms to the contours of a printed circuit board to protect the board's components and is applied in a paint-like fashion by spraying, brushing, dipping and the like. Conformal coatings often have the drawback of containing volatile solvents, (i.e. volatile organic compounds meaning any compound of carbon excluding CO, CO₂, carbonic acid, metallic carbides or carbonates and ammonium carbonates, which participates in atmospheric photochemical reactions, except those designated by the EPA as having negligible photochemical reactivity, see EPA.gov). These paint-like applied conformal coatings typically have about 25-250 μm (micrometers), which is about 1 mil-10 mils, dry coating thickness. Such polymeric coating thickness tend to impede heat dissipation which is undesirable.

Protective thin coatings have also been provided by vacuum processes such as chemical vapor deposition (CVD), in which both solid and volatile products are formed from a volatile precursor through chemical reactions, and the solid products are deposited on the substrate. However vacuum processing builds coating thickness slowly, a disadvantage for fast-moving electronics manufacturing. The vacuum processes have economic drawbacks of requiring specialized chambers and environmental drawbacks in the use of volatile precursors.

Conformal coatings and chemical vapor deposition typically do not react with the surface being coated and are not selective in their coating, which has disadvantages of excess raw material consumption and use of masking, which can be costly and labor intensive for electronics with multiple, minute or complex circuits.

Atom Transfer Radical Polymerization (ATRP) is a living radical polymerization process that has been used in making bulk polymers and in growing polymers on surface bound initiators. A typical ATRP process dissolves a catalyst, a ligand, and a monomer and initiator in a solvent (generally organic) system and uses the dissolved catalyst to polymerize the monomer to form a bulk polymer. Alternatively, initiator may be fixed to a surface, and polymerization results in “brushes” on the surface. The dissolved catalysts utilized are generally transition metals that form a transition metal complex with the initiator, the complex is stabilized by the ligand and the reaction is run in the absence of oxygen and often in the presence of a reducing agent such as ascorbic acid. Both of the above described ATRP processes have drawbacks of requiring deoxygenation of the reaction mixture, use of significant quantities of reducing agent, two step polymerization and/or removal of one or more of the catalyst, ligand and unconsumed monomer from the polymer.

Thus, there is a need for a coating composition capable of rapid, water-resistant coating deposition and a deposition method that is precise (e.g. focuses coating on the corrosion prone metal traces) without the need for masking or expensive application equipment, as well as being cost effective, does not require a vacuum during application and that can be run in the presence of oxygen and in aqueous environment. Such a coating system will preferably be applicable to electronics and in particular to printed circuit boards.

### SUMMARY OF THE DISCLOSURE

Applicants have developed compositions and a process for depositing a polymeric coating on metal surfaces via in situ polymerization of monomer using a modified Atom Transfer Radical Polymerization (ATRP) process to selectively coat portions of a substrate with a water-resistant coating. This invention provides a method of depositing a coating onto a surface by polymerizing in situ fully or partially dissolved monomer in an aqueous medium. The process and can be carried out free of organic solvents, does not require vacuum chambers, and builds coatings at a significantly faster rate relative to vacuum processes, for example dry coating thicknesses of about 25 microns (25,000 nm) can be achieved in processes according to this disclosure with a coating composition contact time of about 10 minutes.

In one aspect of the invention, coating compositions, methods of coating and coated substrates that overcome one or more of the above described disadvantages are provided.

Polymeric water-resistant coatings of the invention can be prepared in aqueous solution utilizing olefinic monomers which may be fully solubilized or at least partially solubilized in water. Based on the polar nature of such monomers, the properties of the polymer coating resulting from polymerization of the polar monomers would be expected to be hydrophilic and a poor candidate for a protective water-resistant coating. Surprisingly, the inventors have found that the polymer coatings of the disclosure provide barrier films effective at protecting circuit boards against damage such as when powered boards are immersed in water. Preferred monomers are soluble in water and/or the polar solvent or solvent system, but once polymerized on the metal trace, the polymer coating is insoluble in water and desirably may be insoluble in the coating composition and/or the polar solvent or solvent system component of the coating composition. In one embodiment, the present disclosure provides a coated substrate comprising at least one conductive metal trace on a non-conductive substrate, the metal trace having deposited thereon an adherent water-resistant polymer coating that is a reaction product of the above described coating composition catalyzed by the presence of a solid metal trace.

In one embodiment of the invention the coating is applied to conductive traces on printed circuit boards.

In one embodiment of the invention the coating is applied to conductive traces on wearable electronic devices. In a preferred embodiment the wearable electronic devices comprise conductive traces attached directly to skin or to a skin-adherent film or patch. Such patches may be used for many purposes such as monitoring body functions such as heart-rate, blood-pressure, monitoring blood oxygen, body temperature, and blood glucose.

In another embodiment of the invention the surface to be coated is a conductive trace within a biological sensor including skin mounted and in-body sensors which monitor a range of biological functions.

In a further embodiment, the reaction product comprises a polymer coating generated by in situ polymerization of the least one olefinic monomer and deposited on the at least one conductive metal trace and optionally deposited on a portion of non-conductive substrates immediately adjacent to the conductive metal trace. Depending on the intended use of the substrate to be coated, extension of the coating beyond the metal trace may be desirable or in some uses it is desirably minimized such as for wearable electronic devices that may benefit from insuring breathability of the electronic device. In a yet further embodiment the polymer coating on the metal trace may have a convex cross-sectional shape for cross-sections taken across the centerline of the metal trace, that is cross-sections perpendicular to the longitudinal axis of the metal trace, e.g. a domed shape extending across the width of the tracing. This domed shape provides a thinner coating on the non-conductive substrate, this gradual reduction reduces abrupt edges on the coating as are found in masked PCBs, which mask edges can act as delamination failure sites. At its thickest point, the polymeric coating may have a thickness of from about 1 to 30 microns at a centerline of maximum thickness of the convex coating, with coating thickness decreasing with increasing distance from said centerline. The center line typically runs parallel to the longitudinal axis of the trace.

According to one aspect of the invention (“Aspect 1”), a method is provided which comprises steps of:

a) contacting a substrate surface comprising one or more metal traces affixed thereto, with a coating composition comprising components:
1) at least one dissolved and/or dispersed radically polymerizable olefinic monomer;
2) at least one dissolved and/or dispersed initiator for living polymerization;
3) at least one dissolved and/or dispersed ligand; and
4) a solvent comprising at least one polar solvent;

b) dissolving an amount of catalytically active metal ions from the one or more metal traces in the presence of the components 1)-4), thereby forming a living polymerization reaction mixture at surfaces of the one or more metal traces;

c) polymerizing the at least one dissolved and/or dispersed radically polymerizable olefinic monomer in situ, in the reaction mixture at the surfaces of the one or more metal traces, thereby forming an adherent polymer film, insoluble in the coating composition, on at least the surfaces of the one or more metal traces.

Further illustrative aspects of the present invention may be summarized as follows:

Aspect 2: The method of Aspect 1 further comprising steps of:

d) removing the substrate surface from contact with the coating composition, optionally rinsing with water, and

e) repeating steps a)-c) using the same or a different coating composition.

Aspect 3: The method of Aspect 1 or 2 wherein the substrate of step a) comprises a circuit board and the one or more metal traces are conductive metal traces.

Aspect 4: The method of Aspect 1-3 wherein the polar solvent of step a) comprises water, preferably consists of water and each of components 1)-3) is soluble in the polar solvent and/or the coating composition; and the process is run without addition of reducing agent and in the presence of oxygen.

Aspect 5: The method of Aspect 1-4 wherein each of components 1)-4) of the coating composition is water soluble and the solvent of step a) comprises water and optionally at least one organic solvent.

Aspect 6: The method of Aspect 1-5 wherein the one or more metal traces comprise copper, zinc, mixtures thereof, alloys thereof or mixtures of alloys thereof.

Aspect 7: The method of Aspect 1-6 comprising adjusting duration of step a)-c) to about 2 to 30 minutes in total thereby producing the adherent polymer coating having a thickness of from 1 to 30 microns on the one or more metal traces.

Aspect 8: A catalyst-free coating composition for living polymerization onto a substrate comprising components:
1) at least one dissolved and/or dispersed radically polymerizable olefinic monomer;
2) at least one dissolved and/or dispersed initiator for living polymerization, preferably an alkyl halide initiator;
3) at least one dissolved and/or dispersed ligand; and
4) at least one polar solvent or a solvent system comprising water;
all based on the total weight of the coating composition; wherein the coating composition comprises no radical polymerization catalyst.

Aspect 9: The catalyst-free coating composition of Aspect 8 wherein the alkyl halide initiator has a halogen alpha to a C-heteroatom unsaturation; preferably the halide in the alkyl halide initiator is bromide, most preferably the alkyl halide is free of fluoride.

Aspect 10: The catalyst-free coating composition of Aspect 8 or 9 wherein the radically polymerizable olefinic monomer comprises at least one of a (meth)acrylate monomer, a vinyl monomer, styrene, acrylonitrile, a (meth)acrylamide monomer, 4-vinyl pyridine, dimethyl(1-ethoxycarbonyl)vinyl phosphate, and mixtures thereof.

Aspect 11: The catalyst-free coating composition of Aspect 8-10 wherein the ligand comprises 2 or more N-containing groups and has no negatively charged oxygen binding groups.

Aspect 12: The catalyst-free coating composition of Aspect 8-11, wherein:
1) about 0.1 to 80% by weight of the at least one dissolved and/or dispersed radically polymerizable olefinic monomer is present;
2) about 0.01 to 5% by weight of the at least one dissolved and/or dispersed initiator for living polymerization is present;
3) about 0.01 to 5% by weight of the at least one dissolved and/or dispersed ligand is present; and
   all based on the total weight of the coating composition.

Aspect 13: A concentrate for use in forming a catalyst-free coating bath comprising:
1) at least one dissolved and/or dispersed radically polymerizable olefinic monomer;
2) at least one dissolved and/or dispersed alkyl halide initiator having a halogen alpha to a C-heteroatom unsaturation wherein said halide is not fluorine;
3) at least one dissolved and/or dispersed ligand comprising 2 or more N-containing groups and having no negatively charged oxygen binding groups, and 4) optionally a solvent in which 1)-3) are soluble.

Aspect 14: The concentrate of Aspect 13 wherein said at least one olefinic monomer is selected from the group consisting of a (meth)acrylate monomer, a vinyl monomer, styrene, acrylonitrile, a (meth)acrylamide monomer, 4-vinyl pyridine, dimethyl(1-ethoxycarbonyl)vinyl phosphate, and mixtures thereof.

Aspect 15: The concentrate of Aspect 13 or 14 wherein said at least one alkyl halide initiator is selected from the group consisting of ethyl 2-bromoisobutyrate; ethyl 2-bromo-2-phenylacetate (EBPA); 2-bromopropanitrile; ethyl 2-bromopropionate; methyl 2-bromopropionate; 1-phenyl ethylbromide; tosyl chloride; 1-cyano-1methylethyldiethyldithiocarbamate; 2-(N,N-diethyldithiocarbamyl)-isobutyric acid ethyl ester; dimethyl 2,6-dibromoheptanedioate and mixtures thereof

Aspect 16: The concentrate of Aspect 13-15 wherein said ligand is selected from the group consisting of 2,2′-bipyridine (“bipy”); 2-picolylamine; Tris(2-pyridylmethyl)amine (TPMA); 1,1,4,7,10,10-Hexamethyltriethylenetetramine (HMTETA); 4,4′,4″-tris(5-nonyl)-2,2′:6′,2″-terpyridine (tNtpy); N,N,N′,N′,N″-pentamethyldiethylenetriamine (PMDETA); Tris(2-dimethylaminoethyl)amine (Me6TREN); N,N-bis (2-pyridylmethyl)octadecylamine (BPMODA); N,N,N′,N′-tetra[(2-pyridal)methyl]ethylenediamine (TPEDA); tris(2-aminoethyl)amine (TREN); tris(2-bis(3-butoxy-3-oxopropyl)aminoethyl)amine (BA6TREN); tris(2-bis(3-(2-ethylhexoxy)-3-oxopropyl)aminoethyl)amine (EHA6TREN); tris(2-bis(3-dodecoxy-3-oxopropyl)aminoethyl)amine (LA6TREN); an imine; a nitrile and mixtures thereof.

Aspect 17: A substrate comprising at least one conductive metal trace affixed to a non-electrically conductive surface of the substrate, and a polymeric coating adhered to surfaces of the at least one metal trace and absent from at least some substrate surfaces.

Aspect 18: The substrate of Aspect 17 wherein the at least one metal trace has a longitudinal axis, and a cross-section of the coating taken in a plane perpendicular to the longitudinal axis of the metal trace has a convex cross-sectional shape and a maximum thickness of about 1 to 30 microns, said coating have lesser thickness at greater distance from the longitudinal axis of the metal trace.

Aspect 19: The substrate of Aspect 17 or 18 wherein said coating is water-resistant for at least 30 minutes of exposure under 1 meter of water under applied electrical power of 3 Volts.

Aspect 20: The substrate of Aspect 17-19 wherein said substrate is a printed circuit board and said metal trace comprises copper, zinc, iron, mixtures thereof, alloys thereof or mixtures of alloys thereof.

Aspect 21: The substrate of Aspect 17-20 wherein the adherent polymeric coating is a polymer made from monomers selected from (meth)acrylate monomer, a vinyl monomer, styrene, acrylonitrile, a (meth)acrylamide monomer, 4-vinyl pyridine, dimethyl(1-ethoxycarbonyl)vinyl phosphate, and mixtures thereof.

Aspect 22: The substrate of Aspect 17-21 wherein the substrate is a printed circuit board and wherein the polymer coating is deposited onto at least one metal circuit formed by the metal traces affixed to the substrate.

Aspect 23: The substrate of Aspect 17-22 wherein the substrate is a wearable electronic device, an on-skin sensor or an in-body sensor; and wherein the polymer coating is deposited onto at least one metal trace affixed to the substrate.

Aspect 24: A substrate comprising a polymer film deposited according to the method of Aspects 1-7.

The following terms as used in the present specification and claims have the meanings as defined herein. A “bath” is understood in the coating arts to mean a composition in a container into which an article to be treated may be immersed or partially immersed to contact the article or portions thereof with the composition in the container, e.g. a coating bath would be understood to mean a coating composition in a container generally used in a process for applying the coating composition. “Stage” as used herein refers to a period of time or a step in a process, e.g. a cleaning stage, a rinsing stage, a coating stage, which also may refer to the bath used to perform the step, e.g. a rinsing stage may refer to a rinse bath used in a rinsing step in a process.

The term “solvent” means liquid that serves as the medium to at least partially dissolve a solute, e.g. component of a coating composition or concentrate according to the disclosure, and may include water, organic molecules, inorganic molecules and mixtures thereof, unless otherwise defined in the description. A “polar solvent” as used herein means a solvent with dielectric constant(s) of about 19 or more and may include protic, i.e. having O—H or N—H bonds, such as for example Water (ε=80), Methanol (ε=33), Ethanol(ε=25) or ammonia (ε=25), and/or aprotic solvents, e.g. DMSO (ε=49), DMF (ε=38), Acetonitrile (ε=37), Acetone (ε=21). A “solvent system” or “solvent mixture” will be understood to comprise two or more solvents.

The term “soluble” with respect to any component means that the component acts as a “solute” which dissolves in a solvent or solvent system or reaction mixture or coating composition thereby forming a solution, which does not form separate phases, whether liquid or solid, e.g. a precipitate, visible to the unaided human eye.

The term “olefinic monomer” as used herein means a monomer having at least one carbon to carbon double bond (C═C) in its structure, this is also known as ethylenic unsaturation. Olefinic monomers may include (meth)acrylate monomers, vinyl monomers and other polymerizable monomers having a C═C structure.

The term “(meth)acrylate monomer” as used herein includes acrylic acid, methacrylic acid, and esters thereof. A vinyl monomer as used herein includes monomers having a vinyl functional group, —CH═CH₂, in their structure.

As used herein, “affixed to a substrate” means adhered, deposited, laminated, printed, etched, pressed, embossed or otherwise attached to the substrate.

Within this disclosure, “water-resistant coating” is defined as a coating layer adhered to a surface and forming a barrier that resists or prevents passage of at least one of oxygen and/or water-containing fluids (liquid or gas) through the coating layer to the coated surface. Water-resistant coating layers desirably resist and/or prevent permeation of oxygen and/or water-containing fluids to the coated surface. One gauge of water-resistant coating performance is prevention or reduction of damage to an assembled printed circuit board from exposure to water or aqueous liquids as a result of immersion, condensation or humidity while powered on, meaning while a voltage is being applied to the printed circuit board. Damage associated with such exposures of inadequately protected circuit boards include electrochemical migration phenomenon, such as dendritic growth and conductive anodic filament formation, as well as corrosive degradation of the conductive traces and conductive connections to electronic components.

For a variety of reasons, it is preferred that coating compositions and concentrates disclosed herein may be substantially free from many ingredients used in compositions for similar purposes in the prior art. Specifically, it is increasingly preferred in the order given, independently for each preferably minimized ingredient listed below, that at least some embodiments of coating compositions or concentrates according to the invention contain no more than 1.0, 0.5, 0.35, 0.10, 0.08, 0.04, 0.02, 0.01, 0.001, or 0.0002 percent, more preferably said numerical values in grams per liter, more preferably in ppm, of each of the following constituents: polymerization catalysts for the olefinic monomer; oxidizing agents such as oxygen, peroxides and peroxyacids, permanganate, perchlorate, chlorate, chlorite, hypochlorite, perborate, hexavalent chromium, sulfuric acid and sulfate, nitric acid and nitrate ions; as well as silicon, fluorine, formaldehyde, formamide, hydroxylamines, cyanides, cyanates, ammonia; rare earth metals; boron, e.g. borax, borate; strontium; and/or free halogen ions, e.g., fluoride, chloride, bromide or iodide. Also, it is increasingly preferred in the order given, independently for each preferably minimized ingredient listed below, that at least some embodiments of as-deposited coatings according to the invention, contain no more than 1.0, 0.5, 0.35, 0.10, 0.08, 0.04, 0.02, 0.01, 0.001, or 0.0002 percent, more preferably said numerical values in parts per thousand (ppt), of each of the aforestated constituents and additionally unreacted monomer or solvent.

The simple term “metal” or “metallic’ will be understood by those of skill in the art to mean a material, whether it be an article or a surface, that is made up of atoms of metal elements, e.g. copper or iron, the metal elements present in amounts of at least, with increasing preference in the order given, 55, 65, 75, 85, or 95 atomic percent, for example the simple term “copper” includes pure copper and those of its alloys that contain at least, with increasing preference in the order given, 55, 65, 75, 85, or 95 atomic percent of copper atoms. A bare metallic surface will be understood to mean a metallic surface in the absence of a coating layer, other than oxides of metals derived from the metallic surface through aging in air and/or water.

Other than in the operating examples, or where otherwise indicated, all numbers expressing quantities of ingredients, reaction conditions, or defining ingredient parameters used herein are to be understood as modified in all instances by the term “about”. Throughout the description, unless expressly stated to the contrary: percent, “parts of’, and ratio values are by weight or mass; the description of a group or class of materials as suitable or preferred for a given purpose in connection with the invention implies that mixtures of any two or more of the members of the group or class are equally suitable or preferred; description of constituents in chemical terms refers to the constituents at the time of addition to any combination specified in the description or of generation in situ within the composition by chemical reaction(s) between one or more newly added constituents and one or more constituents already present in the composition when the other constituents are added; specification of constituents in ionic form additionally implies the presence of sufficient counterions to produce electrical neutrality for the composition as a whole and for any substance added to the composition; any counterions thus implicitly specified preferably are selected from among other constituents explicitly specified in ionic form, to the extent possible; otherwise, such counterions may be freely selected, except for avoiding counterions that act adversely to an object of the invention; molecular weight (MW) is weight average molecular weight unless otherwise specified; the word “mole” means “gram mole”, and the word itself and all of its grammatical variations may be used for any chemical species defined by all of the types and numbers of atoms present in it, irrespective of whether the species is ionic, neutral, unstable, hypothetical or in fact a stable neutral substance with well-defined molecules.

This section provides a general summary of the disclosure and is not a comprehensive disclosure of its full scope or all features, aspects or objectives. These and other features and advantages of this disclosure will become more apparent to those skilled in the art from the detailed description of a preferred embodiment. The drawings that accompany the detailed description are described below.

### BRIEF DESCRIPTION OF THE DRAWINGS

FIG. 1 is photograph of a coated substrate prepared according to the present disclosure;

FIG. 2 is a graph showing the results of current leakage testing run during a 30 minute period of time during which a printed circuit board coated according to the invention and a comparative uncoated printed circuit board were each immersed under 1 meter of water and had 3 volts of electricity applied to the circuit on the printed circuit board of FIG. 1.

FIG. 3 is a graph showing the effect of coating time on the current leakage test results for a series of printed circuit boards coated according to the present disclosure and testing run during a 30 minute period of time during which each printed circuit board coated according to the invention was immersed under 1 meter of water and had 3 volts of electricity applied to the circuit on the printed circuit board.

FIG. 4 is a diagrammatic view of a three-step 210, 310 and 410 process according to one embodiment of the disclosure. The diagram shows one embodiment of a three-stage (meaning three baths, 200, 300 and 400, respectively) coating line, shown at three different process steps 210, 310 and 410, respectively, where coating composition 220, 320 or 420 is contacting a diagrammatic metal trace 100 according to the invention. Also shown is a cross-sectional view A-A of an embodiment of a resulting coated trace 110, e.g. a conductive wire, the cross-section revealing layers of polymeric coating, 250, 350 and 450 produced from the three process steps 210, 310 and 410, respectively.

FIG. 5 is a diagrammatic view of a three-step 510, 530 and 610 process according to another embodiment of the disclosure. The diagram shows an embodiment of a two-stage (meaning two baths, 500 and 600, respectively) coating line, shown at three different process steps, 510, 530 and 610, respectively, contacting a diagrammatic metal trace 100 according to the invention. Also shown is a cross-sectional view A-A of an embodiment of a resulting coated trace, e.g. a conductive wire 110, the cross-section revealing layers of polymeric coating, 551, 553 and 650 produced from the three process steps 510, 530 and 610, respectively. The process utilizes serial contact with bath 500, at different depths of immersion, i₅₁₀ and i₅₃₀ to produce different thicknesses of polymeric coating 551 and 553.

### DETAILED DESCRIPTION OF A PREFERRED EMBODIMENT

The present disclosure provides a catalyst free coating composition useful in a modified Atom Transfer Radical Polymerization (ATRP) process to selectively coat portions of a substrate in a defined pattern with a water-resistant coating by in situ polymerization onto surfaces of the substrate. The polymerization deposits a polymeric coating on substrate surfaces comprising at least one metal surface and catalyst is sourced from the metal surfaces. One benefit of this coating composition is its selective deposition on the catalytic metal and resistance to bulk polymerization of the coating composition in the presence of the catalytic metal.

The invention is useful in coating selected surfaces of circuit boards, in particular, printed circuit boards (PCBs). A printed circuit board is an electrically non-conductive material with electrically conductive traces, also referred to as “lines”, “tracks” or “conductors”, on the board. Electronic components, e.g. integrated circuits (ICs), resistors, capacitors, inductors and connectors, switches and relays, are mounted on the board and traces connect the components to form a working circuit or assembly. The board can be either single sided (one signal layer on top of the board), double sided (two signal layers on top and bottom of the board), or multi-layered (greater than two layers) depending on the number of components and the interconnection density. Components are interconnected to one another by traces on the PCB surface and often embedded among the layers of the board. When inadequately protected, corrosion or breakage of the traces causes failures in electrical conductivity along the trace path and damages can occur associated with electrochemical migration phenomenon such as dendritic growth and conductive anodic filament formation.

In coatings deposited on substrates according to the disclosure, monomer in the coating bath polymerizes on selected portions of the substrate depositing a water-resistant coating on the selected portions of the substrate with some optional deposition on areas of the substrate closely adjacent to the selected portions, without coating the entire surface of the substrate. This provides a cost saving of material for printed circuit boards where the water-resistant is deposited on the metal tracings where typically it is most needed. The in situ polymerization may be run in a polar solvent, such as water, or in a solvent system, meaning a mixture of solvents.

A catalyst-free coating composition for living polymerization onto a substrate is provided. The catalyst-free coating composition comprises components:
1) at least one dissolved and/or dispersed radically polymerizable olefinic monomer;
2) at least one dissolved and/or dispersed initiator for living polymerization, preferably an alkyl halide initiator;
3) at least one dissolved and/or dispersed ligand; and
4) at least one polar solvent or a solvent system comprising water; the coating composition comprises no radical polymerization catalyst.

The present disclosure also provides a reactive coating bath comprising initiator, ligand and monomer in solution in the coating bath and catalyst sourced from the metal substrate, e.g. metal traces, upon which a coating is deposited.

In the instant application, a coating composition and process are provided which are relatively insensitive to the presence of oxygen, in that the process may be run in the presence of ambient air without nitrogen blanket or other oxygen excluding means. The coating compositions according to the disclosure do not require the presence of added dissolved catalyst and deposits on selected surfaces without the need for an initiator bound to the surfaces as an initial step, instead the initiator is dissolved in the coating composition. The process may result in polymers having a narrow molecular weight distribution and low polydispersity. The process can be used to produce a variety of polymers. Other ATRP processes that may be useful in the present invention include adaptations of Supplemental Activator and Reducing Agent (SARA) ATRP.

The coating deposition is an in situ polymerization method of coating a substrate surface with a polymer and may desirably be carried out by immersing or dipping the substrate surface in the coating composition bath containing monomer. The coating forms a water-resistant barrier on coated portions of the substrate. In particular, the coating is localized to portions of the substrate that have a metal trace and closely adjacent areas. The present process uses a solid metal trace to catalyze in situ polymerization of the olefinic monomer in the reaction mixture thereby depositing a polymer coating on the metal trace using a modification of a conventional ATRP process.

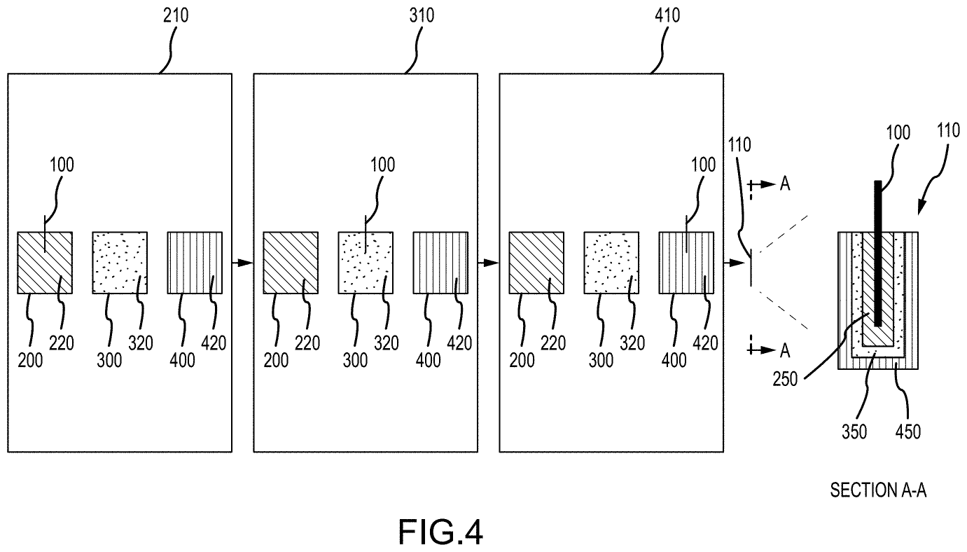

In one embodiment, the polymeric coating may be a block co-polymeric film achieved by contacting the surface to be coated, e.g. a metal trace 100, with more than one monomer containing bath in succession, as shown in FIG. 4. A three-step process according to one embodiment of the disclosure is shown in FIG. 4 as well as a three-stage (meaning three baths, 200, 300 and 400, respectively) coating line, shown at three different process steps 210, 310 and 410, respectively, where coating composition 220, 320 or 420 is contacting a diagrammatic metal trace 100 according to the invention. Coating compositions 220, 320 and 420 each have a different chemical makeup, e.g. dissimilar components, thereby generating different polymeric coatings 250, 350 and 450, respectively, on the metal trace or on a previously deposited coating layer on the metal trace. Also shown is a cross-sectional view A-A of an embodiment of a resulting coated trace 110, e.g. a conductive wire, the cross-section revealing layers of polymeric coating, 250, 350 and 450 produced from the three process steps 210, 310 and 410, respectively. In such cases, different monomers and/or solvents within the baths may be utilized, to produce desired properties. The choice of monomer can be tailored specific to the coating end use and the size of the polymeric block within the copolymer film can be controlled by immersion time of substrate in the bath.

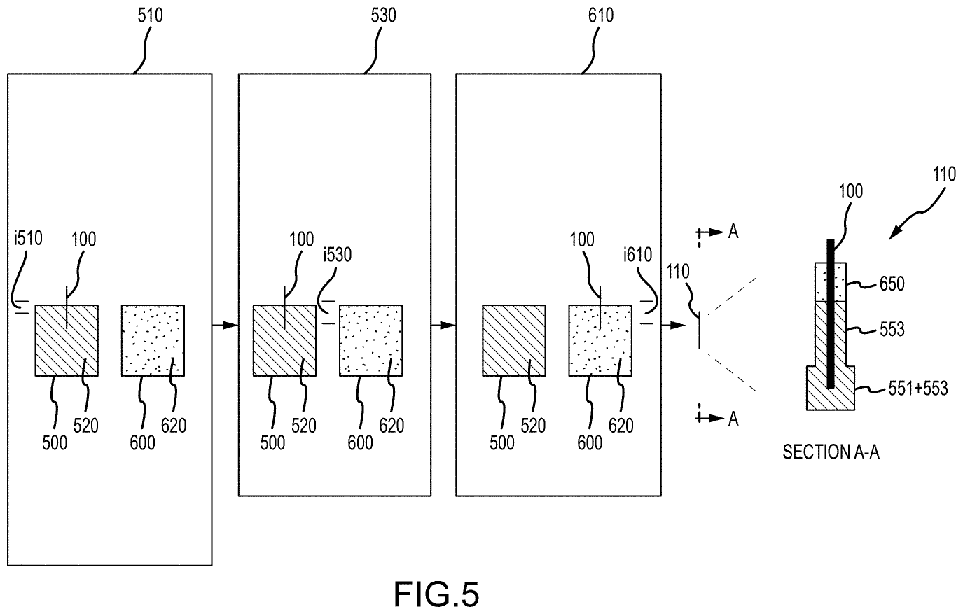

In another embodiment, the invention provides a means to apply compositionally different coatings on different selected areas of a conductive substrate or apply coatings of differing thickness by controlling the immersion depth of the conductive trace in successive immersion steps, see FIG. 5. A three-step 510, 530 and 610 process according to another embodiment of the disclosure is shown in FIG. 5, utilizing a two-stage (meaning two baths, 500 and 600, respectively) coating line. The diagram shows an embodiment of a two-stage (meaning two baths, 500 and 600, respectively) coating line, shown at three different process steps, 510, 530 and 610, respectively, contacting a diagrammatic metal trace 100 according to the invention. Coating compositions 520 and 620 each have a different chemical makeup, e.g. dissimilar components, thereby generating different polymeric coatings: 551 and 553 from bath 520, and coating 650 from bath 620, on the metal trace and/or on a previously deposited coating layer on the metal trace. The three process steps are achieved in the two stage coating line by contacting the metal trace twice with coating composition 520 in bath 500 and once with coating composition 620 in bath 600. Also shown is a cross-sectional view A-A of an embodiment of a resulting coated trace, e.g. a conductive wire 110, the cross-section revealing layers of polymeric coating, 551, 553 and 650 produced from the three process steps 510, 530 and 610, respectively. The process utilizes serial contact with bath 500, at different depths of immersion, i₅₁₀ and i₅₃₀ to produce different thicknesses of polymeric coating 551 and 553. In step 510, the metal trace 100 is immersed to i₅₁₀ depositing polymeric coating 551 and without terminating the living polymerization, the next process step 530 immerses the metal trace 100 from step 510 up to immersion depth i₅₃₀ resulting in a coating 553 on the bare metal trace and additional coating 553 overlaying coating 551. Living polymerization is stopped before step 610 such that immersion to i₆₁₀ deposits polymeric coating 650 on the uncoated portion of the contacted metal trace, and does not coat over the prior applied coatings 551 and 553.

For multi-bath embodiments, it may be desirable to keep the polymer coating “living” as ATRP is generally known as a living polymerization process between stages or alternatively a polymerization termination agent may be introduced in a stage between monomer baths. Examples of useful terminating agents for the sequential multi-bath polymerization can include: DPPH (2,2-diphenyl-1-picrylhydrazyl), BHT (butylated hydroxyl toluene), and nitrobenzene and the like.

For sensor applications, particularly in-body sensors, the coating composition can be tailored to achieve polymeric coatings having specific desirable functions such as to readily pass analyte(s) of interest, such as blood glucose, or to prevent passage of unwanted chemical substances also present in blood, or to provide other properties such as surface friction properties which may be optimized to immobilize the sensor within the body. The invention provides a simple and flexible process to apply highly specialized coatings layers over sensors.

Metals suitable for use as metal surfaces to be coated comprise copper, iron, zinc, nickel, cobalt, titanium, molybdenum, ruthenium, palladium, rhodium and rhenium, mixtures thereof, alloys thereof and mixtures of alloys thereof. A preferred metal article for coating includes conductive metal traces affixed to a substrate according to the present disclosure, which may desirably comprise copper, zinc, iron, mixtures thereof, alloys thereof and mixtures of alloys thereof. Preferably the metal is copper or a copper alloy. The metal traces may comprise, consist essentially of or consist of copper, zinc, iron, mixtures thereof, alloys thereof and mixtures of alloys thereof.

The metal trace pattern determines where the insoluble polymer will be deposited on the substrate as it forms, thus the metal trace can be deposited onto a substrate in any desired pattern and the polymer coating will coat the trace. The entire surface of the substrate can be covered in the metal or just a portion thereof in any pattern. The trace can have any desired thickness and still function as a catalyst for the reaction according to the present disclosure. The present disclosure presents a process that can be utilized to water-resistant very complex patterns and designs on a substrate with a minimal amount of coating material and labor thus keeping material costs and final weight to a minimum.

In one embodiment the substrate is a circuit board having metal traces affixed thereto, preferably a printed circuit board, useful in electronics. Typically, the circuits on a printed circuit board are printed using copper traces and the present disclosed process allows one to deposit a water-resistant coating on the copper circuit without having to coat the entire circuit board.

Suitable solvents useful in the present disclosure are polar solvents, which may be water, organic polar solvents, inorganic polar solvents or mixtures thereof. Small amounts of non-polar solvent may be included in a solvent system or solvent mixture according to the invention provided that the non-polar solvent does not interfere with the operation of the invention. Preferably the solvent comprises water, with or without a second solvent. Water is highly preferred because of its low cost, compatibility with a wide range of substrates, lack of toxicity, ease of use and because it is effective in driving the desired in situ polymerization reaction. Alternatively, the solvent can be a mixture of water with a water miscible organic solvent, if desired. Examples of water miscible organic solvents include alcohols such as methanol, ethanol and isopropanol; acetonitrile and pyridine. One example of a suitable solvent includes a 1:1 vol:vol mixture of water and isopropyl alcohol (IPA).

The reaction according to the present disclosure can be conducted in an open atmosphere of air. That is, the polymerization reaction need not be in an oxygen free or oxygen depleted reaction mixture or atmosphere. The process does not require the use of a vacuum or a blanket of any other gas.

Suitable olefinic monomers useful in the present disclosure are desirably soluble in the coating composition and/or the solvent, e.g. polar solvent, present in the coating composition. The process according to the present disclosure can be conducted with a single olefinic monomer or a mixture of olefinic monomers. Examples of suitable olefinic monomer types include (meth)acrylate monomers, as defined herein, vinyl monomers as defined herein; as nonlimiting examples monomers, which may be substituted and unsubstituted with additional functional groups, may include: acrylic acid, methacrylic acid, esters of acrylic acid and esters of methacrylic acid, acrylamides; methacrylamides, styrene, acrylonitrile, 4-vinyl pyridine, n-vinyl formamide, dimethyl(1-ethoxycarbonyl)vinyl phosphate, and mixtures thereof. Preferred monomers include hydroxyalkyl (meth)acrylates. A particularly preferred monomer is an ester of methacrylic acid, such as hydroxyethyl methacrylate.

Suitable monomers are preferably soluble in water. A feature of a preferred embodiment of the present disclosure is that while the suitable monomers are all desirably soluble in the coating composition and/or the solvent, e.g. polar solvent, present in the coating composition, the polymer formed in situ from the monomers and deposited onto the metal trace is not soluble in the coating composition and/or the solvent, e.g. polar solvent, present in the coating composition. Total monomer concentration in a coating solution according to the present disclosure may be at least in increasing order of preference, about 0.05, 0.1, 0.25, 0.5, 0.75, 1.0, 2.0, 2.5, 3.0, 3.5, 4.0, 4.5, 5.0, 5.5, 6.0% by weight, and at least for economy may be not more than about 7.0, 8.0, 9.0, 10, 11, 12, 13, 14, 15, 16, 17, 18, 19, 20, 25, 30, 35, 40, 45, 50, 55, 60, 65 or 75% by weight. Higher percentages of monomer may be used provided that the increased amount does not interfere with obtaining the benefits of the invention. In some embodiments, total monomer concentration in a coating composition according to the present disclosure desirably may be from 0.1 to 50% by weight, preferably from 5 to 15% by weight based on the total weight of the coating solution.

Suitable ligands are desirably soluble in the coating composition and/or the solvent, e.g. polar solvent, present in the coating composition. The suitable ligand is generally a nitrogen-containing organic molecule able to form a complex with the metal catalyst such that the metal complex may also be soluble in the solvent and/or the coating composition. Desirably a ligand according to the disclosure may be an amine, which can be primary, secondary or tertiary; and may be saturated or unsaturated, cyclic or acyclic, aromatic or non-aromatic. Examples of suitable ligands include: 2,2′-bipyridine (“bipy”); 2-picolylamine; Tris(2-pyridylmethyl)amine (TPMA); and 1,1,4,7,10,10-Hexamethyltriethylenetetramine (HMTETA). Other examples include 4,4′,4″-tris(5-nonyl)-2,2′:6′,2″-terpyridine (tNtpy); N,N,N′,N′,N″-pentamethyldiethylenetriamine (PMDETA); Tris(2-dimethylaminoethyl)amine (Me₆TREN); N,N-bis (2-pyridylmethyl)octadecylamine (BPMODA); N,N,N′,N′-tetra[(2-pyridal)methyl]ethylenediamine (TPEDA); tris(2-aminoethyl)amine (TREN); tris(2-bis(3-butoxy-3-oxopropyl)aminoethyl)amine (BA₆TREN); tris(2-bis(3-(2-ethylhexoxy)-3-oxopropyl)aminoethyl)amine (EHA₆TREN); and tris(2-bis(3-dodecoxy-3-oxopropyl)aminoethyl)amine (LA₆TREN). The basic characteristics of a suitable ligand include: an organic molecule containing 2 or more N-containing groups, preferably amines and more preferably tertiary or aromatic amines, and no negatively charged oxygen binding groups, such as carboxylate or phenolate groups. As the N-containing group one can also use imines or nitriles. Examples of other known ligands for ATRP can be found in Chem. Rev. 2007, 107, 2270-2299, which is hereby incorporated by reference. The total ligand(s) concentration in a coating solution according to the present disclosure may be at least in increasing order of preference, about 0.005, 0.0075, 0.01, 0.05, 0.1, 0.25, 0.5, 0.75% by weight, and at least for economy may be not more than about 0.9, 1.0, 1.5, 2.0, 2.5, 3.0, 3.5, 4.0, 4.5, 5.0, 5.5, 6.0, 6.5, or 7.5% by weight, and desirably may be from about 0.01 to about 5% by weight, preferably from about 0.1 to about 1% by weight based on a total weight of the coating solution.

The initiators useful in the present disclosure are organic molecules having one or more radically transferable atoms or groups and are desirably soluble in the coating composition and/or the solvent, e.g. polar solvent, present in the coating composition. In preferred embodiments, the initiators include alkyl halide initiator molecules having a halogen functional group bonded to the C-alpha to a C-heteroatom unsaturation. Generally, the C-heteroatom unsaturation can be an ester function. The alkyl halides used as initiators may comprise one or more such halogen functional groups. The preferred halogens are bromide, chloride or iodide, and preferably a bromide. In the presently disclosed process the halogen atom on the alkyl halide is not fluorine. Nonlimiting examples of suitable alkyl halides include alkyl 2-bromopropionates, such as ethyl 2-bromopropionate and methyl 2-bromopropionate; alkyl 2-bromoisobutyrates, such as methyl 2-bromoisobutyrate and ethyl 2-bromoisobutyrate; and ethyl 2-halo-2-phenylacetates, such as ethyl 2-bromo-2-phenylacetate (EBPA) and ethyl 2-chloro-2-phenylacetate (ECPA). Suitable alkyl halide initiators are organic molecules containing a Cl, Br, or I alpha to a C-heteroatom unsaturation site as in the above-described examples. Other examples of suitable ATRP alkyl halide initiators include 2-bromopropanitrile; 1-phenyl ethylbromide; tosyl chloride; and dimethyl 2,6-dibromoheptanedioate. Other halogen-free ATRP initiators may alternatively be used, for example 1-cyano-1-methylethyldiethyldithiocarbamate; 2-(N,N-diethyldithiocarbamyl)-isobutyric acid ethyl ester. The total initiator(s) concentration in a coating solution according to the present disclosure may be at least in increasing order of preference, about 0.005, 0.0075, 0.01, 0.05, 0.1, 0.25, 0.5, 0.75% by weight, and at least for economy may be not more than about 0.9, 1.0, 1.5, 2.0, 2.5, 3.0, 3.5, 4.0, 4.5, 5.0, 5.5, 6.0, 6.5, or 7.5% by weight, and desirably may be from about 0.01 to about 5% by weight, preferably from about 0.1 to about 1% by weight based on a total weight of the coating solution.

Optional components for the composition and concentrates may be selected from wetting agents, rheology modifiers, biocides, biostatic materials.

In one embodiment the coating solution is provided as a concentrate comprising: the ligand, the monomer(s) and the initiator. The concentrate can be formulated to be diluted with a solvent to form the full bath or alternatively as a bath replenisher as is known in the art to supplement a previously formed bath. Alternatively, the coating solution can be provided as a ready to use solution.

A process of making a coating solution of the present disclosure comprises forming a coating solution comprising: the ligand, the initiator, the monomer(s) and the solvent. The coating solution components are stirred together in a container to form a bath, for example from single components, two or more separate combinations of components or a concentrate of the coating solution.

A method of forming a polymer film on a substrate according to the disclosure comprise: a) contacting a substrate surface comprising one or more metal traces affixed thereto, with a coating composition comprising the above described coating solution; b) dissolving an amount of catalytically active metal ions from the one or more metal traces in the presence of the coating composition, thereby forming a living polymerization reaction mixture at surfaces of the one or more metal traces; c) polymerizing the radically polymerizable olefinic monomer in situ, in the reaction mixture at the surfaces of the one or more metal traces, thereby forming an adherent polymer film, insoluble in the coating composition, on at least the surfaces of the one or more metal traces.

The amount of contacting time varies depending on the size of the trace, concentration of the bath and desired thickness of the polymeric coating. At least for economy's sake, contact time desirably ranges from 2 to 30 minutes, preferably from 2 to 15 minutes, shorter contact times may be achieved if desired.

The process can be run in the open atmosphere and does not require a vacuum or a blanketing gas. The process also does not require a heated bath or any heating step. The process can be run at any temperature above the freezing point of the solvent, preferably up to about 50° C., most preferably the bath is neither heated nor cooled and is run at ambient temperature of about 25° C. Surprisingly, the disclosed process produces little or no sludge in the bath even after many hours of running the process in the bath. For example, the coating process may produce less than in increasing order of preference, 10, 8, 6, 4, 2, or 1 g/l solid sludge after 24 hours of contact with a PCB-B-25A test printed circuit; the disclosed process desirably may produce little or no polymeric coating on the container used to hold the bath under the same process parameters.

Although one might run the process by applying the coating solution directly onto the substrate in a variety of procedures known in the art, the metal traces are preferably immersed in a bath of the coating composition, which aids in consistently providing monomer to the trace and wetting the trace. In addition, although the process is not very affected by O₂, running the process as a bath reduces the influence of O₂ even further. Once a sufficient amount of polymer has been deposited onto the metal trace, the substrate is removed from the coating bath and placed in a rinse bath of deionized water for a period of time from 2 to 20 seconds, preferably for less than 10 seconds. This rinse bath is followed by drying of the substrate, for example using forced air.

Coated substrates according to the disclosure comprise at least one metal trace affixed to a substrate and a coating polymerized on at least one surface of the metal trace thereby forming a polymeric coating. In one embodiment the substrate is an electrically non-conductive material and the metal trace is an electrically conductive material, preferably a printed circuit board. Some polymeric coating may also be deposited onto substrate areas closely adjacent to the metal trace. In one embodiment, the polymer coating may extend no more than 2 millimeters beyond the edge of the metal trace and optionally no more than 1, 0.5, 0.25, 0.1 or 0.05 millimeter beyond the edge of the metal trace.

Metal traces may have any shape according to their function. In one embodiment, desirable metal traces may comprise those having a metal trace length that is greater than a metal trace width, suitable examples include wire conductors and PCB metal traces, with a longitudinal axis running parallel to the metal trace length. In a further embodiment, the polymer coating on the metal trace may have a convex cross-sectional shape for cross-sections taken across the centerline of the metal trace, that is cross-sections perpendicular to the longitudinal axis of the metal trace. At its thickest point, the polymeric coating may have a thickness of from about 1 to 30 microns at a centerline of maximum thickness of the convex coating, with coating thickness decreasing with increasing distance from said centerline. The center line typically runs parallel to the longitudinal axis of the trace. The thickest part of the coating is directly over the metal trace and the coating thins as one moves out from a centerline of the metal trace. Thus, when looking at the cross-sectional shape of the coating if one takes the thickest portion of the coating as a centerline then the coating thickness decreases as one moves away from the centerline of the coating. Desirably, the polymeric coating has a maximum thickness of from 1 to 30 microns, preferably a maximum thickness of about 2 to less than 30 microns. Thus, the formed coating has a non-uniform thickness, and this is unlike where an entire substrate is covered with a uniform thickness of the coating solution or the circuits are masked and then a uniform coating is applied to the masked substrate. Once one removes the mask the coating has a uniform thickness where applied. As can be surmised the masking process can be very time consuming if the traces are numerous and especially if they have complex shapes. The masking leaves an abrupt edge on the coating and this can lead to delamination and peeling problems of this coating. The present disclosed process requires no masking, results in edges that thin out from the metal trace and thus are less susceptible to delamination or peeling and require less coating material.

The coating according to the disclosed process provides a water-resistant coating to the metal trace. Advantages of the process disclosed herein include that polymerization and coating can be accomplished in a single step rather than a multi-step process, because the polymerization and deposition take place in situ on the substrate. Thus, one can avoid prior processes requiring suspending a finished polymer in a solvent and suspension or emulsifying agents in a coating bath. For example, the present disclosed process can be used to coat a metal trace with a coating of polyhydroxyethylmethacrylate (poly-HEMA) in suit in a single step in water. Utilizing the prior processes would require first forming the poly-HEMA and then solubilizing in a solvent such as ethanol prior to applying it in a coating.

In an alternative embodiment, successive applications using the process of the disclosure may advantageously be used to form block copolymers and/or different polymeric coatings on different areas of the substrate.

The coating formed according to the present disclosure is water-resistant, meaning it is water-resistant to immersion for at least 30 minutes under 39 inches of water while under electrical power. The coating also significantly reduces the formation of dendrites between adjacent metal traces on a substrate. Dendrite formation is a problem with existing systems and can lead to failure of the circuit due to a short circuit forming between two traces via the dendrite. Use of the present disclosed process results in a coating that curtails dendrites formed between traces of a test circuit board when tested as described in the Examples below; preferably no dendrites are formed. This is far below the numerous dendrites formed during this test using conventional coating processes.

Prior to a coating step utilizing a coating composition in accordance with the present invention, a metal surface of a metal trace may be cleaned using any method known in the art for removing contaminants from the metal surface, such as spraying with an alkaline cleaner. The metal trace surface may also be rinsed prior to coating, either with water alone or with a pre-rinse solution comprising one or more substances capable of further improving performance, e.g. adhesion, water-resistance, or the like of the polymeric coating subsequently formed on the metal trace surface. So-called pre-conditioning treatments may be employed, but coating processes in the absence of a pre-conditioning step are preferred.

Within this specification, embodiments have been described in a way which enables a clear and concise specification to be written, but it is intended and will be appreciated that embodiments may be variously combined or separated without departing from the invention. For example, it will be appreciated that all preferred features described herein are applicable to all aspects of the invention described herein.

In some embodiments, the invention herein can be construed as excluding any element or process step that does not materially affect the basic and novel characteristics of a composition, article or process. Additionally, in some embodiments, the invention can be construed as excluding any element or process step not specified herein.

Although the invention is illustrated and described herein with reference to specific embodiments, the invention is not intended to be limited to the details shown. In the experiments disclosed in the present specification a selected olefinic monomer was used in an exemplary ATRP process to deposit an in situ polymerized coating on metal traces of copper on a printed circuit board. It is but one example of an article that can benefit from a polymeric coating of the present invention. Rather, various modifications may be made in the details within the scope and range of equivalents of the claims and without departing from the invention.

### EXAMPLES

### Test Substrates:

Unless otherwise described herein, test substrates were commercially available, IPC-Association Connecting Electronics Industries (formerly the Institute for Printed Circuits, aka IPC) approved, PCB-B-25A test printed circuit boards (PCB). These test printed circuit boards were IPC/Surface Mount Technology Association (SMTA) compliant and met the guidelines for use in testing solder masks (IPC-SM-804C) and conformal coatings (IPC-CC-830A). Each test printed circuit board was 1.6 mm (0.062 inch) thick, FR-4 grade glass-reinforced epoxy laminate and was a simple print-and-etch with bare copper traces, which do not form a complete circuit, that is no current passes through the PCB-B-25A absent a corrosion induced conductive electrical pathway, i.e. a short circuit.

### Water-Resistance Test:

Effectiveness of the coating in providing water-resistance to the printed circuit boards of the examples was tested as follows: The coated test circuit boards were connected to an electrical voltage supply in the off position, immersed in water to a depth of 1 meter, and 3 V of electricity was then applied for 30 minutes. Where no complete circuit is present, no current passes. Current readings increase from zero with the onset of corrosion based degradation of the conductive traces resulting in short circuits resulting in current passage. During the 30 minute immersion, an in-line ammeter was used to detect current leakage from the electrified printed circuit board by measuring current passage through the circuit over the test period with less milliamps being better. Readings were taken every 1 sec. for 30 minutes.

Performance of the coating was also judged by the number of dendrites visible between traces, with fewer dendrites showing better performance, where dendrites and formation of visually observable oxides are indicators of corrosion.

### Example 1

A coating solution containing 500 g deionized water, 70 g hydroxyethylmethacrylate, 2 g 2,2′-bipyridine, and 2 g ethyl alpha-bromoisobutyrate was prepared with ˜100 RPM, stirring with a stir bar in an open coating bath container in contact with air. Prior to processing the PCBs, the coating solution was observed to be clear and colorless with no visible phase separation or solid precipitate.

The test printed circuit boards were immersed in the coating solution in the open coating bath container for 10 minutes. No nitrogen or other oxygen isolating gas blanket was used to exclude ambient oxygen from contact with the coating solution. After 10 minutes immersion, the test boards were removed from the coating solution, immersed in a deionized water rinse for 5 seconds and then blown dry with forced air. A coating layer was observed to have been deposited primarily over the Cu traces, with some halo of coating deposited on the nonconductive circuit board surface surrounding the metal traces.

The test printed circuit boards coated as described above and comparative uncoated test printed circuit boards were subjected to the Water-resistance Test described above.

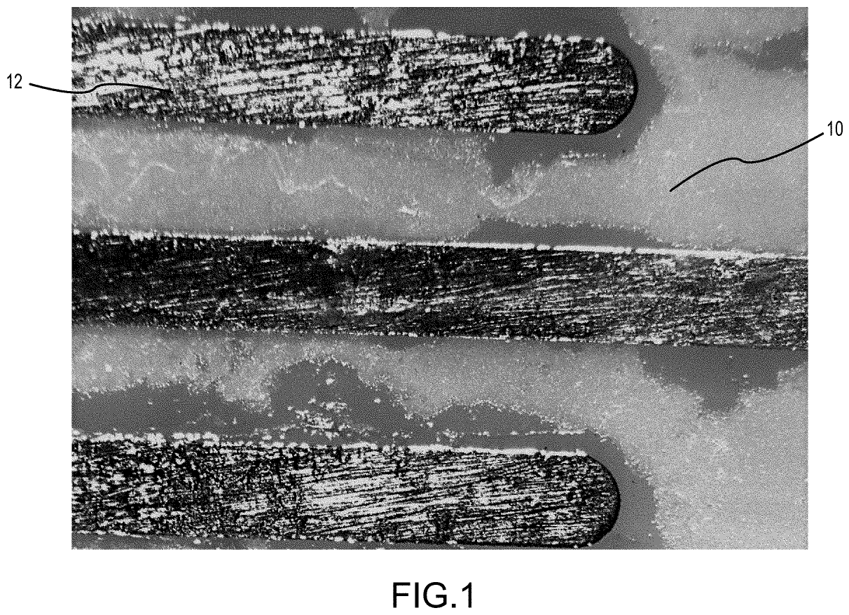

The photograph in FIG. 1 shows a portion of a test PCB substrate coated according to Example 1, with three copper traces 12 on the substrate 10. No dendrites can be seen formed between the traces 12.

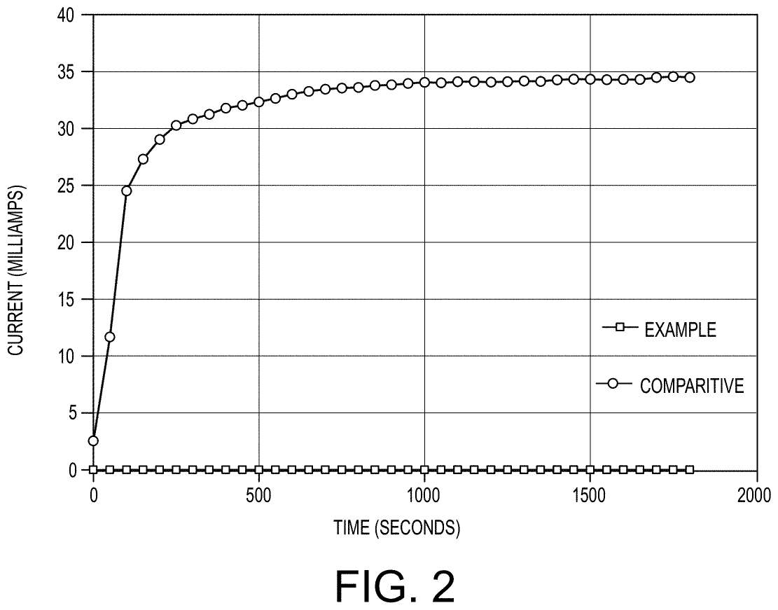

FIG. 2 shows a graph of current leakage test results from the Water-resistance Test of a test PCB substrate coated according to Example 1 and a comparative uncoated test PCBs. In order to prevent a runaway current spike from the predicted outcome of measuring an uncoated board, an 85 ohm resistor was placed into the circuit for the uncoated board testing only. The uncoated board failed quickly, rapidly approaching the maximum of 35 milliamps possible with the safety resistor in place. Amounts of current leakage were measured at one second increments over the period with less being better. Graph line markers are provided at 50 second intervals. For the coated test PCBs, measured current leakage rose from 0.003 milliamps to 0.005 milliamps over the 30 minute test period. FIG. 2 shows this negligible level of current leakage as a flat line near zero.

This significant drop in current leakage for the PCBs coated according to the invention shows that the coating reduces corrosion of the traces.

### Example 2

In a second example, a series of PCB-B-25A circuit boards were placed in a coating bath of the same coating solution as described in Example 1 for a series of different immersion times of 2, 4, 6 or 8 minutes, respectively. No nitrogen or other oxygen isolating gas blanket was used to exclude ambient oxygen from contact with the coating solution. The test circuit boards were removed from the coating solution, immersed in a deionized water rinse for 5 seconds and then blown dry with forced air.

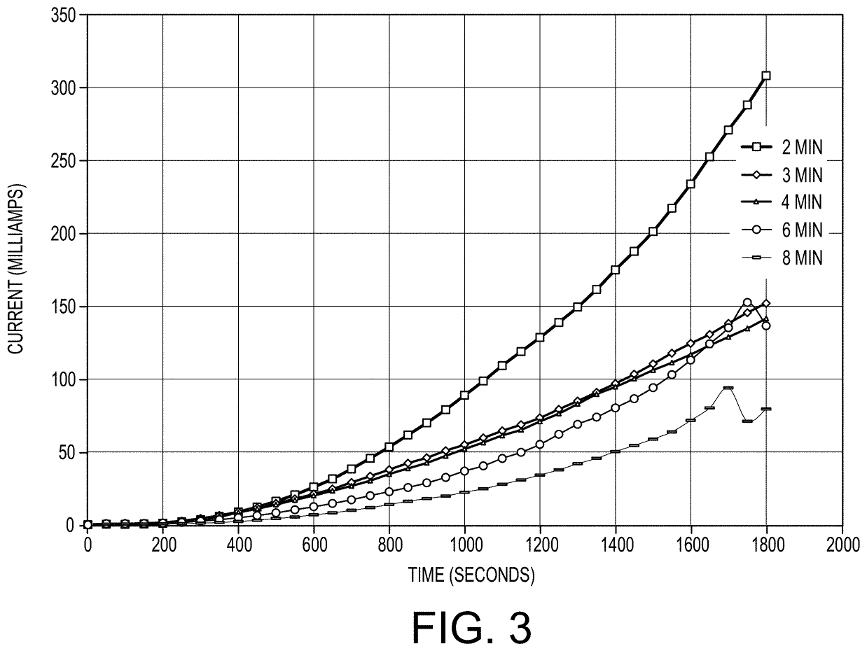

The test printed circuit boards were subjected to the Water-resistance Test described above. Current leakage measured at one second increments over the period with less being better. The current leakage results for these examples are shown in FIG. 3. Graph line markers are provided every 50 seconds. As can be seen in FIG. 3 the longer the coating time, the more effective the coating was at water-resistance the circuit board as shown by a reduced measured current leakage.

The present disclosure demonstrates a method of water-resistant coating of a substrate and in particular for water-resistant coating of a printed circuit board. The coating is localized to the actual metal traces printed on the board with a small amount of coating on the substrate closely adjacent to the metal trace. The process is highly efficient and can be run in an open bath using water as a solvent. The process is an in situ modification of the ATRP process utilizing a metal trace as the catalyst for the ATRP process. The modified process is rapid and efficient and can be adapted to a wide range of substrates and metal traces.

The foregoing disclosure has been described in accordance with the relevant legal standards, thus the description is exemplary rather than limiting in nature. Variations and modifications to the disclosed embodiment may become apparent to those skilled in the art and do come within the scope of the disclosure. Accordingly, the scope of legal protection afforded this disclosure can only be determined by studying the following claims.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

We claim:

1. A method of forming a polymer film on a substrate comprising steps of:
a) contacting a substrate surface comprising one or more metal traces affixed thereto, with a coating composition comprising components:
1) at least one dissolved and/or dispersed radically polymerizable olefinic monomer;
2) at least one dissolved and/or dispersed initiator for living polymerization;
3) at least one dissolved and/or dispersed ligand; and
4) a solvent comprising at least one polar solvent;
b) dissolving an amount of catalytically active metal ions from the one or more metal traces in the presence of the components 1)-4), thereby forming a living polymerization reaction mixture at surfaces of the one or more metal traces;
c) polymerizing the at least one dissolved and/or dispersed radically polymerizable olefinic monomer in situ, in the reaction mixture at the surfaces of the one or more metal traces, thereby forming an adherent polymer film, insoluble in the coating composition, on at least the surfaces of the one or more metal traces.

2. The method of claim 1 further comprising steps of:
d) removing the substrate surface from contact with the coating composition, optionally rinsing with water, and
e) repeating steps a)-c) using the same or a different coating composition.

3. The method of claim 1 wherein the substrate of step a) comprises a circuit board and the one or more metal traces are conductive metal traces.

4. The method of claim 1 wherein the polar solvent of step a) comprises water, preferably consists of water and each of components 1)-3) is soluble in the polar solvent and/or the coating composition; and the process is run without addition of reducing agent and in the presence of oxygen.

5. The method of claim 1 wherein each of components 1)-4) of the coating composition is water soluble and the solvent of step a) comprises water and optionally at least one organic solvent.

6. The method of claim 1 wherein the one or more metal traces comprise copper, zinc, mixtures thereof, alloys thereof or mixtures of alloys thereof.

7. The method of claim 1 comprising adjusting duration of step a)-c) to about 2 to 30 minutes in total thereby producing the adherent polymer coating having a thickness of from 1 to 30 microns on the one or more metal traces.

8. A catalyst-free coating composition for living polymerization onto a substrate comprising components:
1) at least one dissolved and/or dispersed radically polymerizable olefinic monomer;
2) at least one dissolved and/or dispersed initiator for living polymerization, preferably an alkyl halide initiator;
3) at least one dissolved and/or dispersed ligand; and
4) at least one polar solvent or a solvent system comprising water;
all based on the total weight of the coating composition; wherein the coating composition comprises no radical polymerization catalyst.

9. The catalyst-free coating composition of claim 8 wherein the alkyl halide initiator has a halogen alpha to a C-heteroatom unsaturation; preferably the halide in the alkyl halide initiator is bromide, most preferably the alkyl halide is free of fluoride.

10. The catalyst-free coating composition of claim 8 wherein the radically polymerizable olefinic monomer comprises at least one of a (meth)acrylate monomer, a vinyl monomer, styrene, acrylonitrile, a (meth)acrylamide monomer, 4-vinyl pyridine, dimethyl(1-ethoxycarbonyl)vinyl phosphate, and mixtures thereof.

11. The catalyst-free coating composition of claim 8 wherein the ligand comprises 2 or more N-containing groups and has no negatively charged oxygen binding groups.

12. The catalyst-free coating composition of claim 8, wherein:
1) about 0.1 to 80% by weight of the at least one dissolved and/or dispersed radically polymerizable olefinic monomer is present;
2) about 0.01 to 5% by weight of the at least one dissolved and/or dispersed initiator for living polymerization is present;
3) about 0.01 to 5% by weight of the at least one dissolved and/or dispersed ligand is present; and
all based on the total weight of the coating composition.

13. A concentrate for use in forming a catalyst-free coating bath comprising:
1) at least one dissolved and/or dispersed radically polymerizable olefinic monomer;
2) at least one dissolved and/or dispersed alkyl halide initiator having a halogen alpha to a C-heteroatom unsaturation wherein said halide is not fluorine;
3) at least one dissolved and/or dispersed ligand comprising 2 or more N-containing groups and having no negatively charged oxygen binding groups, and
4) optionally a solvent in which 1)-3) are soluble.

14. The concentrate of claim 13 wherein said at least one olefinic monomer is selected from the group consisting of a (meth)acrylate monomer, a vinyl monomer, styrene, acrylonitrile, a (meth)acrylamide monomer, 4-vinyl pyridine, dimethyl(1-ethoxycarbonyl)vinyl phosphate, and mixtures thereof.

15. The concentrate of claim 13 wherein said at least one alkyl halide initiator is selected from the group consisting of ethyl 2-bromoisobutyrate; ethyl 2-bromo-2-phenylacetate (EBPA); 2-bromopropanitrile; ethyl 2-bromopropionate; methyl 2-bromopropionate; 1-phenyl ethylbromide; tosyl chloride; 1-cyano-1methylethyldiethyldithiocarbamate; 2-(N,N-diethyldithiocarbamyl)-isobutyric acid ethyl ester; dimethyl 2,6-dibromoheptanedioate and mixtures thereof.

16. The concentrate of claim 13 wherein said ligand is selected from the group consisting of 2,2′-bipyridine (“bipy”); 2-picolylamine; Tris(2-pyridylmethyl)amine (TPMA); 1,1,4,7,10,10-Hexamethyltriethylenetetramine (HMTETA); 4,4′,4″-tris(5-nonyl)-2,2′:6′,2″-terpyridine (tNtpy); N,N,N′,N′,N″-pentamethyldiethylenetriamine (PMDETA); Tris(2-dimethylaminoethyl)amine (Me₆TREN); N,N-bis (2-pyridylmethyl)octadecylamine (BPMODA); N,N,N′,N′-tetra[(2-pyridal)methyl]ethylenediamine (TPEDA); tris(2-aminoethyl)amine (TREN); tris(2-bis(3-butoxy-3-oxopropyl)aminoethyl)amine (BA₆TREN); tris(2-bis(3-(2-ethylhexoxy)-3-oxopropyl)aminoethyl)amine (EHA₆TREN); tris(2-bis(3-dodecoxy-3-oxopropyl)aminoethyl)amine (LA₆TREN); an imine; a nitrile and mixtures thereof.

17. A substrate comprising at least one conductive metal trace affixed to a non-electrically conductive surface of the substrate, and a polymeric coating adhered to surfaces of the at least one metal trace and absent from at least some substrate surfaces.

18. The substrate of claim 17 wherein the at least one metal trace has a longitudinal axis, and a cross-section of the coating taken in a plane perpendicular to the longitudinal axis of the metal trace has a convex cross-sectional shape and a maximum thickness of about 1 to 30 microns, said coating have lesser thickness at greater distance from the longitudinal axis of the metal trace.

19. The substrate of claim 17 wherein said coating is water-resistant for at least 30 minutes of exposure under 1 meter of water under applied electrical power of 3 Volts.

20. The substrate of claim 17 wherein said substrate is a printed circuit board and said metal trace comprises copper, zinc, iron, mixtures thereof, alloys thereof or mixtures of alloys thereof.

21. The substrate of claim 17 wherein the adherent polymeric coating is a polymer made from monomers selected from (meth)acrylate monomer, a vinyl monomer, styrene, acrylonitrile, a (meth)acrylamide monomer, 4-vinyl pyridine, dimethyl(1-ethoxycarbonyl)vinyl phosphate, and mixtures thereof.

22. The substrate of claim 17 wherein the substrate is a printed circuit board and wherein the polymer coating is deposited onto at least one metal circuit formed by the metal traces affixed to the substrate.

23. The substrate of claim 17 wherein the substrate is a wearable electronic device, an on-skin sensor or an in-body sensor; and wherein the polymer coating is deposited onto at least one metal trace affixed to the substrate.

24. A substrate comprising a polymer film deposited according to the method of claim 1.
